(19) United States
(12) Patent Application Publication
(10) Pub. No.: US 2024/0379504 A1
(43) Pub. Date: Nov. 14, 2024

(54) SIDE-EXPOSED EMBEDDED TRACE SUBSTRATE AND MANUFACTURING METHOD THEREOF

(71) Applicant: Zhuhai YUEXIN Semiconductor Limited Liability Company, Guangdong (CN)

(72) Inventors: XIANMING CHEN, Guangdong (CN); LEI FENG, Guangdong (CN); LINA JIANG, Guangdong (CN); JUN GAO, Guangdong (CN); BENXIA HUANG, Guangdong (CN); WENJIAN LIN, Guangdong (CN)

(21) Appl. No.: 18/655,631

(22) Filed: May 6, 2024

(30) Foreign Application Priority Data
May 8, 2023 (CN) 2023105138750

(51) Int. Cl. H01L 23/482; H01L 21/48; H01L 23/00; H01L 23/485; H01L 23/498

(52) U.S. Cl. CPC H01L 23/4821; H01L 21/4857; H01L 23/4824; H01L 23/485; H01L 23/49816; H01L 24/03; H01L 24/08; H01L 2224/03462; H01L 2224/03614; H01L 2224/08113; H01L 2224/08268

(57) ABSTRACT

A side-exposed embedded trace substrate includes a dielectric layer, a first wiring layer and a first wiring layer embedded in the dielectric layer. An outer surface of the first wiring layer is not higher than a surface of the dielectric layer, and the first wiring layer includes a pad having a groove to increase a side-exposed area of the pad. The contact area between the substrate and the solder during package welding is increased so that the welding reliability is enhanced, the problem of poor welding or poor reliability caused by trace embedding may be avoided, and poor filling of the packaging material due to insufficient gap between the device and the pad during packaging may be prevented.

### CROSS-REFERENCE TO RELATED APPLICATION AND CLAIM OF PRIORITY

This application claims the benefit under 35 USC § 119 of Chinese Patent Application No. 2023105138750 filed on May 8, 2023, in the China Intellectual Property Office, the entire disclosure of which is incorporated herein by reference for all purposes.

### BACKGROUND

### 1. Technical Field

The disclosure relates to the field of semiconductor packaging technology, and more particularly, to a side-exposed embedded trace substrate and a manufacturing method thereof.

### 2. Background Art

With the development trend of light, thin, short and small electronic products, the traditional wire bonding technology cannot meet the demand of higher I/O pins, and the application of flip-chip technology in wire with high I/O pins is gradually expanding. As an advanced packaging technology, it puts higher requirements on the integration level of packaging substrate, while the Embedded Trace Substrate (ETS) technology fits this requirement well.

### SUMMARY

In view of the foregoing, it is an object of the disclosure to provide a side-exposed embedded trace substrate and a manufacturing method thereof.

In view of the above objects, in a first aspect, the disclosure provides a side-exposed embedded trace substrate, comprising:
a dielectric layer and a first wiring layer embedded in the dielectric layer;
wherein an outer surface of the first wiring layer is not higher than a surface of the dielectric layer, and the first wiring layer comprises a pad having a groove to increase a side-exposed area of the pad.

In some embodiments, the groove is located at an edge or a middle of the pad.

In some embodiments, the depth of the groove is less than the thickness of the first wiring layer, and the pad is used to mount a device.

In some embodiments, the depth of the groove is equal to the thickness of the first wiring layer, and the pad is used to weld a device.

In some embodiments, the first wiring layer comprises a first sub-layer and a second sub-layer below the first sub-layer, an upper surface of the first sub-layer being flush with a surface of the dielectric layer; the groove is surrounded by the first sub-layer and exposes a dielectric layer surrounded by the second sub-layer.

In a second aspect, the embodiments of the disclosure provide a manufacturing method of a side-exposed embedded trace substrate, comprising:
(a) providing a substrate; wherein the substrate comprises a dielectric layer and a first wiring layer embedded in the dielectric layer;
(b) applying a first resist layer on the substrate, and forming a first opening by exposure and development; wherein the first opening exposes at least a partial region of a pad of the first wiring layer;
(c) etching the first wiring layer exposed by the first opening to form a groove in a partial region of the pad; and
(d) removing the first resist layer to obtain the side-exposed embedded trace substrate.

In some embodiments, the process of etching is selected from acid etching or alkaline etching.

In some embodiments, the first opening is located at an edge of the pad or a middle of the pad.

In some embodiments, the depth of the groove is less than the thickness of the first wiring layer, and the pad is used to mount a device; or the depth of the groove is equal to the thickness of the first wiring layer, and the pad is used to weld a device.

In some embodiments, step (a) comprises:
(a1) providing a carrier plate;
(a2) applying a first anti-plating film layer on the carrier plate, and forming a second opening by exposure and development;
(a3) forming a first sub-layer of the first wiring layer in the second opening by electroplating;
(a4) applying a second anti-plating film layer on the first anti-plating film layer and the first sub-layer, and forming a third opening by exposure and development; wherein the second anti-plating film layer corresponding to the side-exposed region of the pad is retained;
(a5) forming a second sub-layer of the first wiring layer in the third opening by electroplating;
(a6) removing the first anti-plating film layer and the second anti-plating film layer;
(a7) forming a third anti-plating film layer on the carrier plate and the first wiring layer, and forming a fourth opening by exposure and development;
(a8) forming a metal post in the fourth opening by electroplating; (a9) removing the third anti-plating film layer;
(a10) laminating a dielectric layer, thinning the dielectric layer until the metal post is exposed;
(a11) forming a second wiring layer on the dielectric layer; and
(a12) removing the carrier plate.

In some embodiments, the projections of the first opening and the third opening on the substrate do not overlap.

In some embodiments, step (a11) comprises:
applying a seed layer on the dielectric layer;
applying a fourth anti-plating film layer on the seed layer, and forming a second wiring layer pattern by exposure and development; and
forming the second wiring layer by electroplating.

In some embodiments, the carrier plate comprises a first metal layer and a second metal layer; step (a12) comprises:
separating the first metal layer and the second metal layer, and etching the second metal layer in contact with the dielectric layer.

It can be seen from the above that the disclosure provides a side-exposed embedded trace substrate and a manufacturing method thereof, wherein a groove is provided in a pad region of a first wiring layer embedded in a dielectric layer so as to increase the side-exposed area of the pad, so as to increase the contact area between the substrate and the solder during package welding and enhance the welding reliability; avoid the problem of poor welding or poor reliability caused by wire embedding; at the same time, the problem of poor filling of the packaging material due to insufficient “gap” between the device and the pad during packaging is solved.

### BRIEF DESCRIPTION OF THE DRAWINGS

In order to more clearly illustrate the technical solutions of the disclosure or the related art, a brief description will be given below with reference to the accompanying drawings which are required to be used in the description of the embodiments or the related art. It is obvious that the drawings in the description below are only embodiments of the disclosure, and other drawings can be obtained from these drawings by a person skilled in the art without involving any inventive effort. In the drawings, the thickness and shape of some of the layers and regions may be exaggerated for better understanding and ease of description.

FIG. 1 is a schematic structural diagram of a side-exposed embedded trace substrate provided by an embodiment of the disclosure;

FIG. 2 is a schematic structural diagram of a side-exposed embedded trace substrate provided by another embodiment of the disclosure;

FIGS. 3A-3F are schematic cross-sectional views of an intermediate structure in each step of a manufacturing method of a side-exposed embedded trace substrate according to an embodiment of the disclosure; and

FIGS. 4A-4Z are schematic cross-sectional views of an intermediate structure in each step of a manufacturing method of a side-exposed embedded trace substrate according to another embodiment of the disclosure.

### DETAILED DESCRIPTION OF THE EMBODIMENTS

The purpose, aspects, and advantages of the disclosure will become more apparent from the detailed description set forth below when taken in conjunction with the specific embodiments and the appended drawings.

It should be noted that, unless otherwise defined, technical or scientific terms used in the embodiments of the disclosure shall have the ordinary meaning as understood by one of ordinary skill in the art to which the disclosure belongs. The use of “first”, “second”, and similar terms in the embodiments of the disclosure does not denote any order, quantity, or importance, but rather is used to distinguish one element from another. The word “comprising” or “comprises”, and the like, means that the elements or items preceding the word encompass the elements or items listed after the word and equivalents thereof, but do not exclude other elements or items. “Up”, “down”, “left”, “right”, etc. are only used to indicate a relative positional relationship, which may change accordingly when the absolute position of the object being described changes.

Embedded Trace Substrate (ETS) is manufactured based on Coreless substrate technology.

By using Coreless technology, one of the outermost traces (front and back) is embedded in the dielectric layer, which can avoid etching the side wall of the trace when the subsequent seed layer is etched, and improve the wiring capacity; at the same time, compared with the traditional MSAP and SAP process, it has higher trace flatness. In addition, because the traces are embedded in the dielectric layer, it helps to reduce the thickness of the substrate.

However, the conventional embedded trace substrate has five sides of one trace except the front side embedded in the dielectric layer. In the welding process of package, the traditional non-embedded trace has five sides in contact with solder, while the embedded trace has only one side in contact with the solder, which results in insufficient reliability and one side in contact easily affected by shear stress to lead to poor welding.

In addition, when a passive device needs to be surface-mounted (Surface Mounted Technology, SMT) on the pad, a “gap” between the device and the pad is insufficient, so that the phenomenon that a packaging material cannot flow between the small gaps easily occurs, and a packaging cavity is further caused.

In view of the above, exemplary embodiments of the disclosure provide a side-exposed embedded trace substrate, which combines the advantages of a conventional non-embedded trace substrate with the advantages of an embedded trace substrate, and can solve the problem of poor welding or poor reliability caused by trace embedding during package welding in the existing coreless embedded trace packaging technology; at the same time, the problem of poor filling of the packaging material due to insufficient “gap” between the device and the pad during packaging is solved.

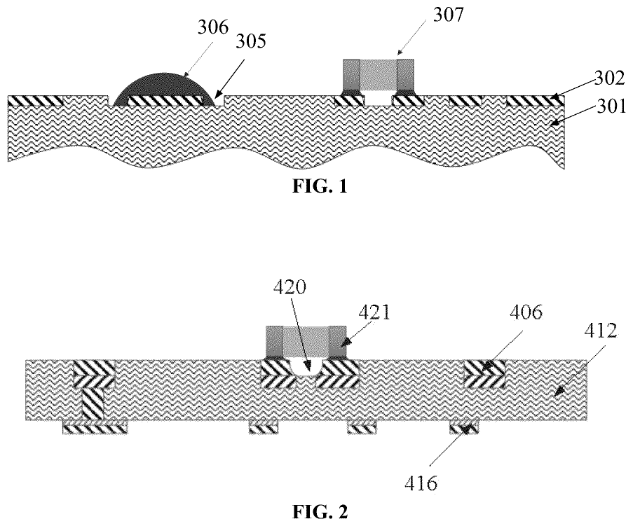

Specifically, as shown in FIGS. 1 and 2, the side-exposed embedded trace substrate comprises:
dielectric layers 301, 412; first wiring layers 302 and 406, which are embedded in the dielectric layers 301 and 412; wherein, the first wiring layers 302, 406 comprises pads (not labeled) that comprise grooves 305, 420 to increase a side-exposed area of the pads.

Note that the side edge of the pad in the embodiments of the disclosure refers to the edge in the direction perpendicular to the substrate surface, and does not refer exclusively to the outer periphery of the pad.

In such a technical solution, a groove is used to expose the side surface of the pad so as to increase the contact area between the solder 306 and the pad, thereby avoiding the problem of poor welding or poor reliability; in addition, the grooves also increase the gap between the pads and the devices 307, 421 so that the packaging material can be sufficiently filled by flow, improving the quality of the packaging.

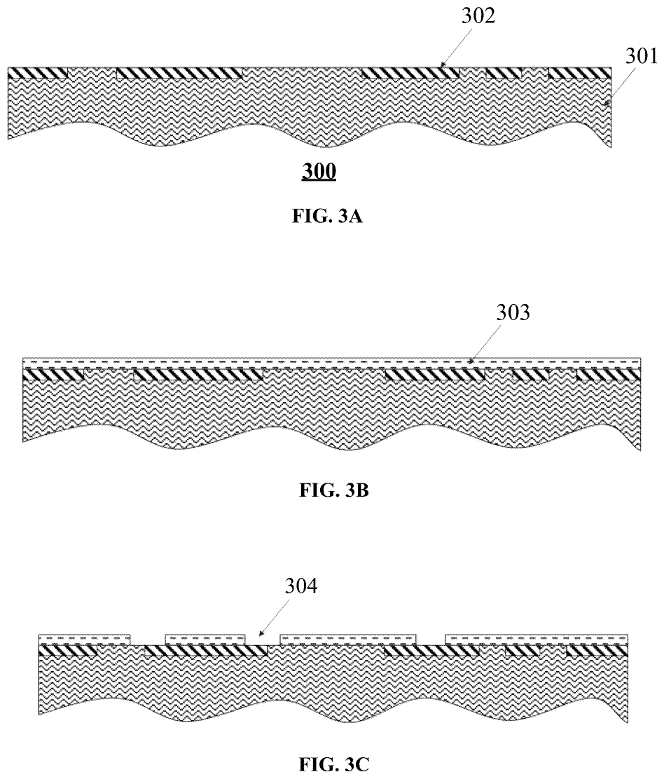

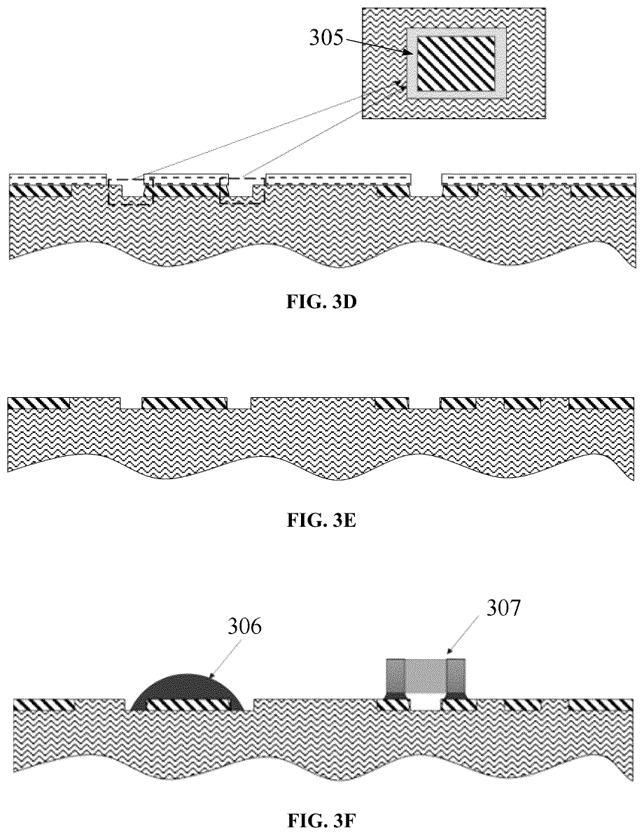

In some embodiments, the groove is located at the edge (e.g. left side of FIG. 1) or the middle (e.g. right side of FIG. 1, FIG. 2) of the pad. It should be noted that the groove may be located on one side of the pad or may be located on multiple sides of the pad (see FIG. 3D), which is not limited in the disclosure.

In addition, the width of the groove and the depth of the groove can also be designed according to design requirements. The disclosure is illustrated below.

In some embodiments, the depth of the groove 420 is less than the thickness of the first wiring layer 406 and the pad is used to mount the device 421. Such an arrangement of the grooves 420 can ensure mounting stability for mounting the device 421, satisfy the requirement of filling the packaging material, and avoid waste of the packaging material.

In some embodiments, as shown in FIG. 1, the depth of the groove 305 is equal to the thickness of the first wiring layer 302 and the pad is used to weld the device.

In some embodiments, the first wiring layer 406 includes a first sub-layer 4061 and a second sub-layer 4062, the surface of the first sub-layer 4061 being flush with the surface of the dielectric layer 412; the groove 420 is located in the first sub-layer 4061 and has a dielectric layer 412 at its bottom.

Exemplary embodiments of the disclosure also provide a manufacturing method of a side-exposed embedded trace substrate. FIGS. 3A-3E show schematic cross-sectional views of intermediate structures in each step of a manufacturing method of a side-exposed embedded trace substrate according to an embodiment of the disclosure.

The manufacturing method includes the following steps: a substrate 300 is provided—step (a), as shown in FIG. 3A. Here, the substrate 300 includes a dielectric layer 301 and a first wiring layer 302 flush with each other in surface.

The number of layers of the dielectric layer included in the substrate 300 is not limited to one layer, and the subsequent flow is only demonstrated for a substrate including one dielectric layer. The disclosure does not limit the number of layers of the substrate, the thickness of each layer, and the type of material of each layer.

It should be noted that the substrate 300 can use a Coreless technology or a conventional CCL (Copper Clad Laminate) layer-adding technology to prepare a multi-layer dielectric layer, and the interlayer conduction mode can include copper column conduction, laser hole conduction or mechanical hole conduction, etc. and the details are not limited.

Next, a first resist layer 303 is applied to the substrate and exposed and developed to form a first opening 304—step (b), as shown in FIGS. 3B-3C. The first opening 304 at least partially overlaps the pad region of the first wiring layer 302. By locating the first opening 304, it is advantageous to ensure that the groove formed by the subsequent etching is located in the pad area, increasing the side-exposed area of the pad.

Optionally, the first opening 304 is located at the edge of the pad or in the middle of the pad.

Alternatively, the process of applying the first resist layer 303 may be to conform to a dry resist film or to coat a resist material, such as a photoresist.

It should be noted that a resist film layer is usually applied on both sides of a substrate, and the figure only shows an embedded trace surface, and the resist film layer is applied on a non-embedded surface only to protect a wiring layer from being etched, and no special etching treatment is performed, which is not the focus of the embodiments of the disclosure, and thus not shown.

The first wiring layer of the first opening is then etched to form a groove 305—step (c), as shown in FIG. 3D. Here, the position of the groove 305 is instantly required to be etched. Alternatively, the process of etching is selected from acid etching or alkaline etching.

The top right structure in FIG. 3D is a top view of the pad area. It should be noted that the location of the grooves is exemplary only, and the grooves 305 may be provided on any one side, two sides, three sides, or four sides in the horizontal direction of the pad depending on design requirements. Of course, the groove 305 may also be provided in the middle of the pad.

Finally, the first resist layer 303 is removed, i.e. to obtain a side-exposed embedded trace substrate—step (d), as shown in FIG. 3E. As can be understood by those skilled in the art, when the resist film layer is applied on both sides of the substrate, the resist film layer on both sides is removed at the same time. A person skilled in the art would have been able to select a suitable stripping process according to requirements, which is not limited in the disclosure.

In some embodiments, the depth of the groove 305 is equal to the thickness of the first wiring layer 302 and the pad is used to weld the device. As shown in FIG. 3F, the groove can expose the side edge of the pad, and welding is performed on the side-exposed pad, not only increasing the contact area between the solder 306 and the substrate, but also longitudinally wrapping the substrate wire with the solder, enhancing the ability to resist shear stress in the horizontal direction without breaking, i.e. improving the welding reliability.

In addition, the passive component 307 is welded on such a weld pad, and after the device is welded, a “gap” is formed at the bottom of the device, which facilitates the flow filling of the packaging resin material during the subsequent packaging process of the substrate, so as to avoid the technical problem of poor glue flow at the bottom of the device due to the excessively small “gap”.

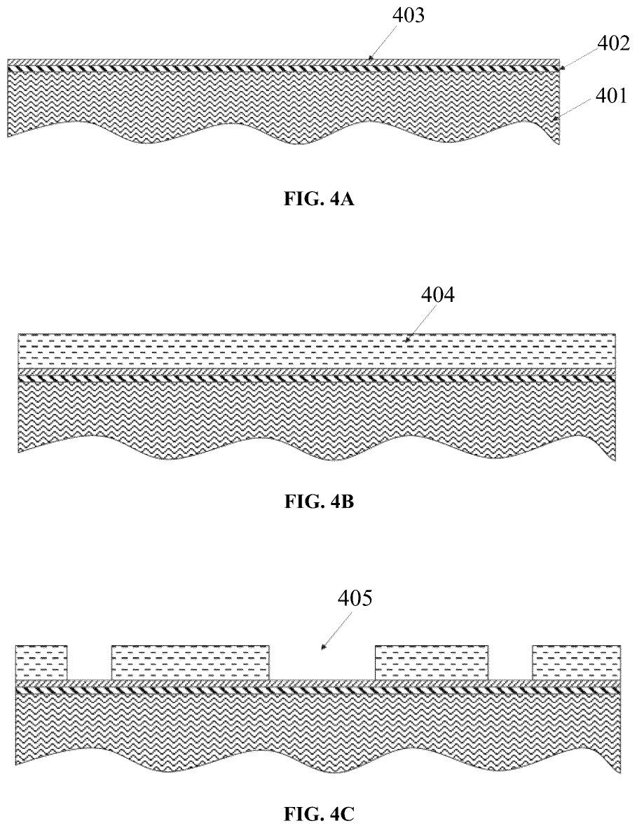

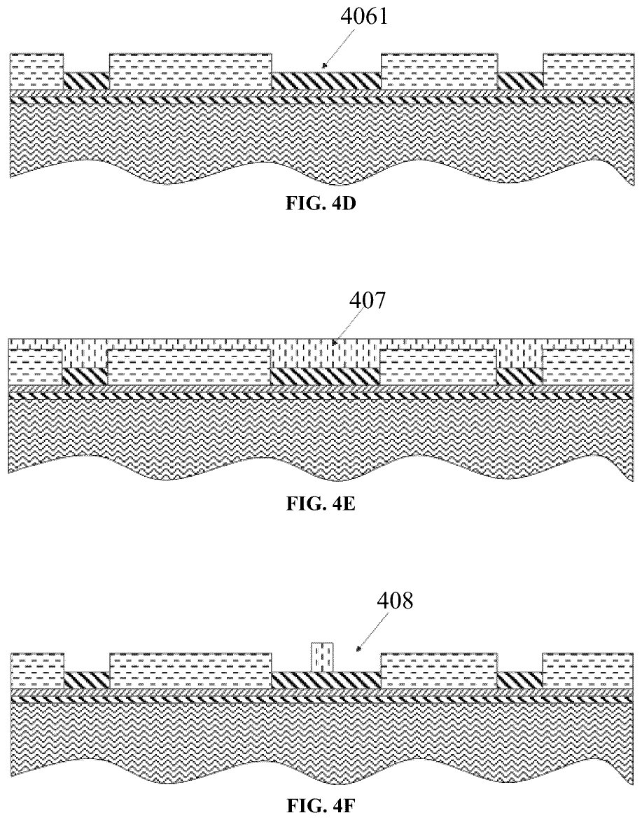

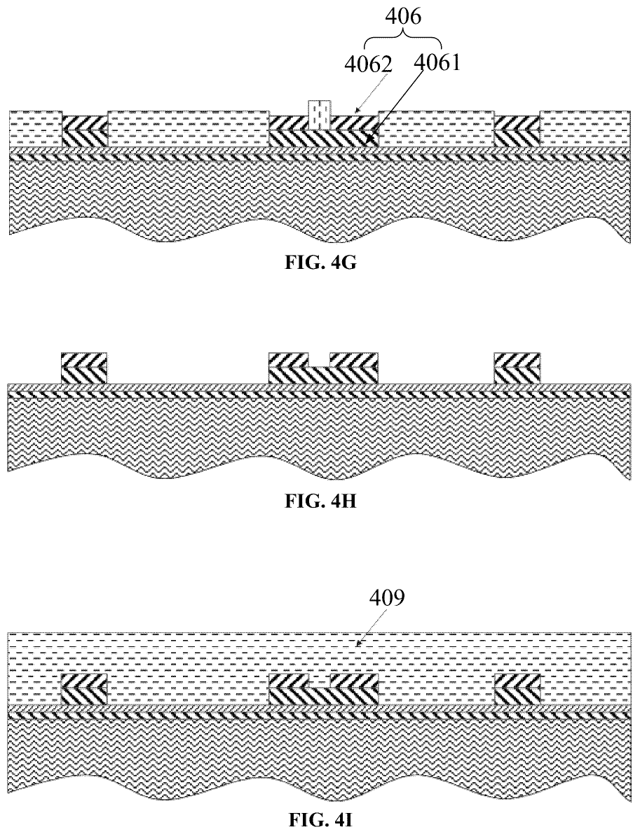

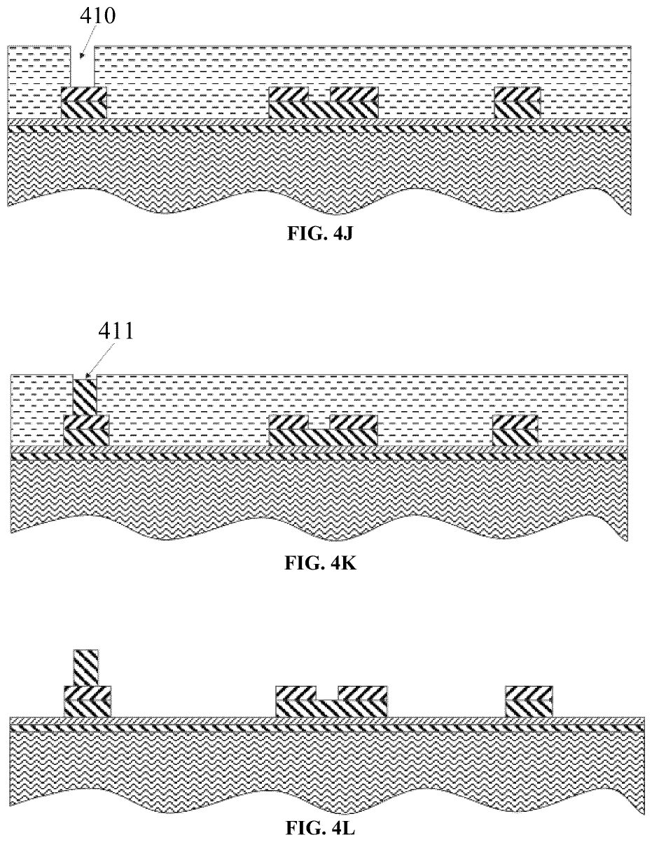

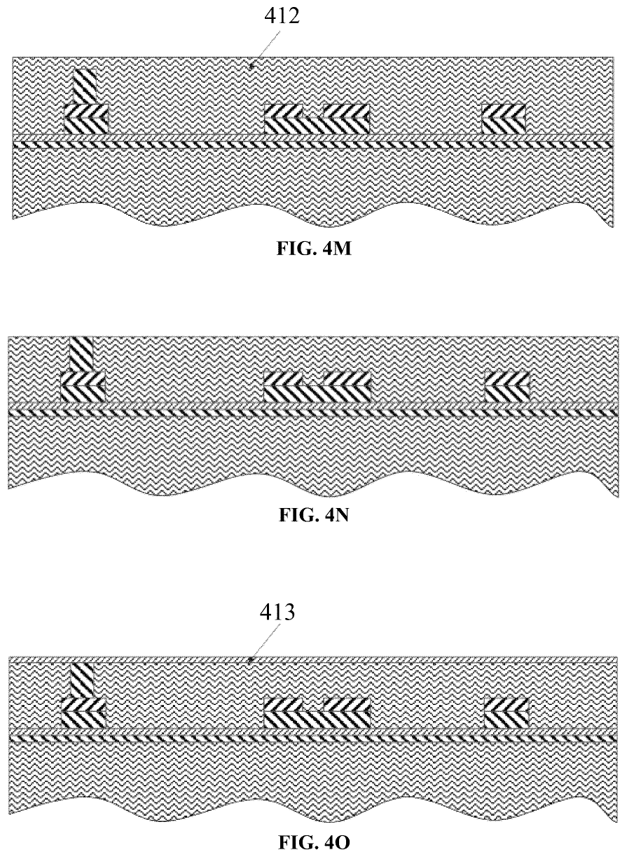

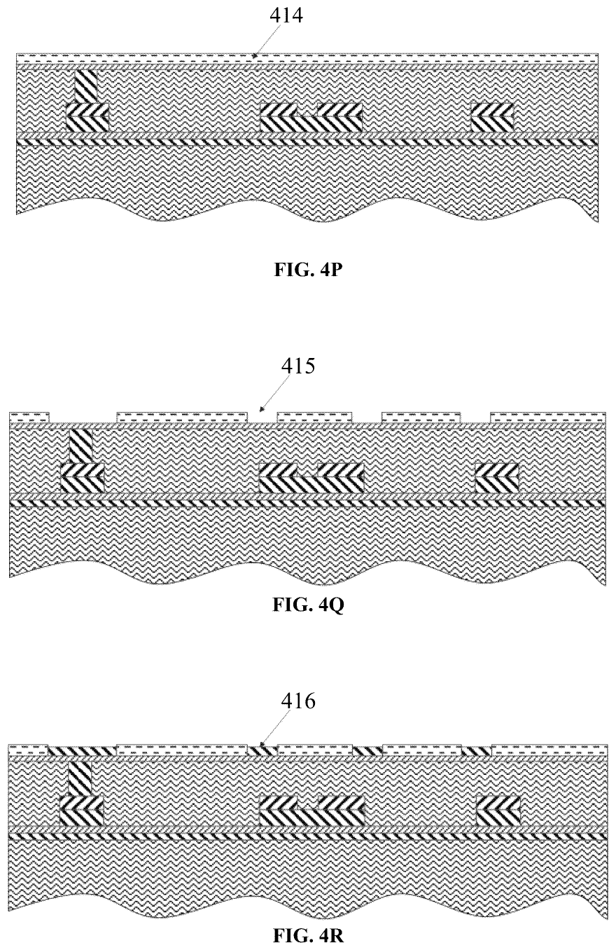

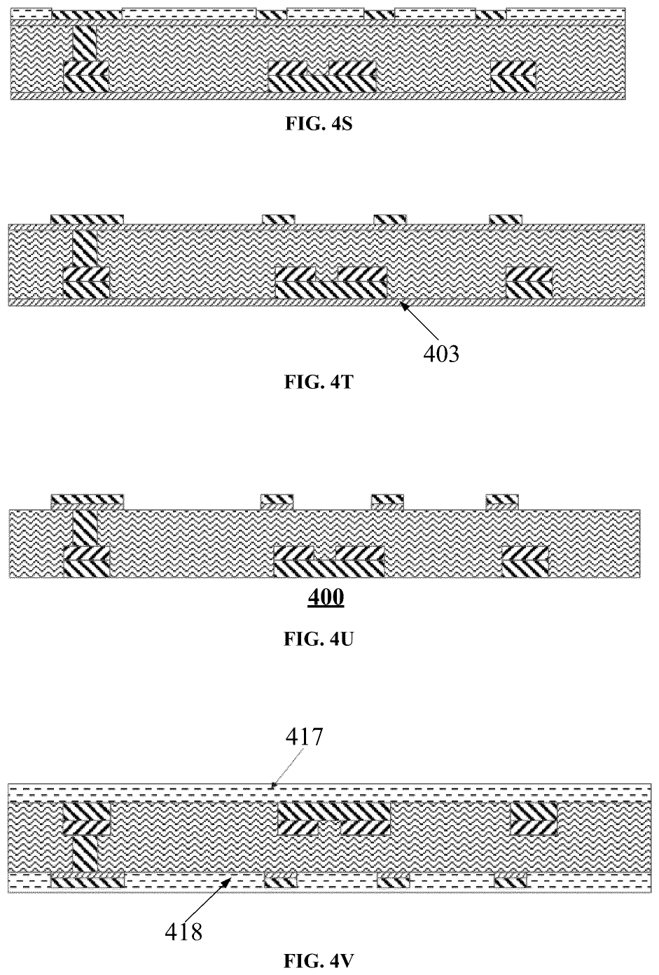

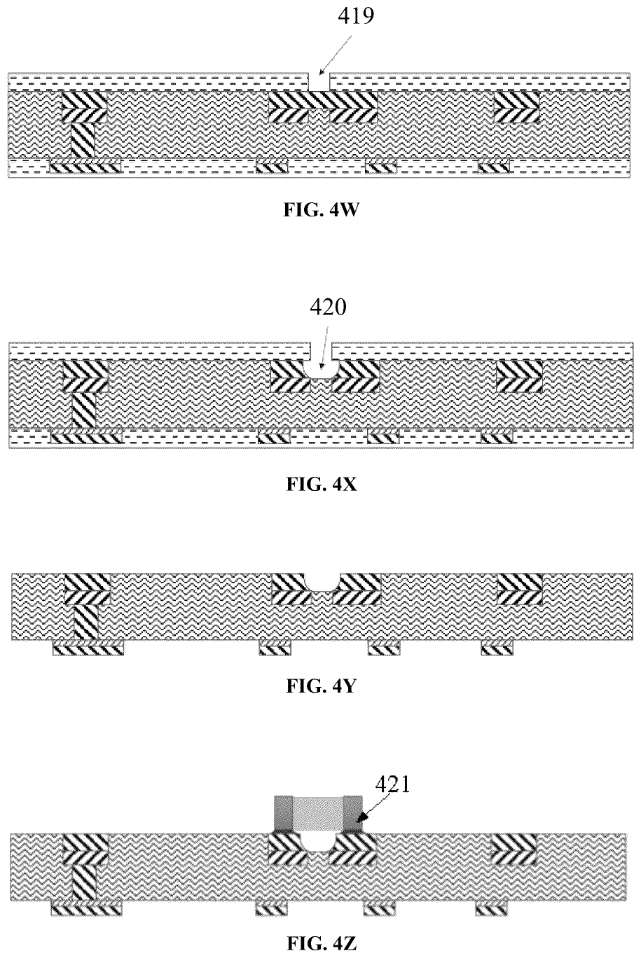

FIGS. 4A-4Y show schematic cross-sectional views of intermediate structures in each step of a manufacturing method of a side-exposed embedded trace substrate according to another embodiment of the disclosure; wherein, the exemplary embodiment includes a specific manufacturing method of a substrate (see FIGS. 4A-4U).

The manufacturing method includes the following steps: a carrier plate is provided—step (a1), as shown in FIG. 4A. It should be noted that the carrier plate may have a double-sided symmetrical structure such as CCL, and FIG. 4A shows only one-sided structure.

The carrier plate includes a carrier plate 401, a first metal layer 402 and a second metal layer 403; wherein, the first metal layer 402 is mounted to the carrier plate 401. Alternatively, both the first metal layer 402 and the second metal layer 403 may be physically separated.

Alternatively, the first metal layer 402 is a copper foil having a thickness of 16 to 20 μm, such as 18 μm; the second metal layer 403 is a 2 to 3 μm copper foil.

Next, a first anti-plating film layer 404 is applied on the carrier plate, and a second opening 405 is formed by exposure and development—step (a2), as shown in FIGS. 4B-4C. Here, the second opening 405 leaks out the region requiring the plating wire.

Then, a first sub-layer 4061 forming a first wiring layer is plated in the region of the second opening 405—step (a3), as shown in FIG. 4D. By way of example, the thickness of the first sub-layer 4061 may be half of the thickness of the first wiring layer, or a specific plating thickness may be set according to actual needs, which is not limited in the disclosure.

Next, a second anti-plating film layer 407 is applied on the first anti-plating film layer 404 and the first sub-layer 4061, and a third opening 408 is formed by exposure and development—step (a4), as shown in FIGS. 4E-4F.

The second anti-plating film layer 407 corresponding to the side-exposed region of the pad is retained. With this arrangement, the second anti-plating film layer at this location can act as an etch stop layer, thereby precisely controlling the depth of the etched groove.

As will be appreciated by those skilled in the art, the third opening 408 exposes a location where electroplating needs to continue, i.e. the third opening is smaller than the second opening.

Then, a second sub-layer 4062 forming the first wiring layer is plated in the third opening—step (a5), as shown in FIG. 4G.

Next, the first anti-plating film layer 404 and the second anti-plating film layer 407 are removed—step (a6), as shown in FIG. 4H.

Then, a third anti-plating film layer 409 is formed on the carrier plate and the first wiring layer, and a fourth opening 410 is formed by exposure and development—step (a7), as shown in FIGS. 41-4J.

Next, a metal post 411 is electroplated in the fourth opening—step (a8), as shown in FIG. 4K.

Then, the third anti-plating film layer 409 is removed—step (a9), as shown in FIG. 4L.

Next, the dielectric layer 412 is laminated, and the dielectric layer 412 is thinned until the metal post 411 is exposed—step (a10), as shown in FIGS. 4M-4N.

The material of the dielectric layer 412 may be Resin Coated Copper (RCC), resin coated film (RCF), or a glass fiber-free resin material such as one selected from the group consisting of liquid crystal polymer, bismaleimide triazine (BT) resin, prepreg, Ajinomoto Build-up (ABF) film, epoxy, and polyimide resin, which is not limited in the invention.

Optionally, the process of thinning the dielectric layer 412 is selected from grinding, plasma etching, or sand blasting.

Then, a second wiring layer 416 is formed on the dielectric layer 412—step (a11), as shown in FIGS. 40-4R.

The surface mounted technology has a certain requirement for the thickness of the wiring layer, and the groove being too deep and too large may easily lead to uneven filling. By providing a double-layer electroplating scheme in which two anti-plating film layers are electroplated twice, the dielectric layer which subsequently replaces the second anti-plating film layer can be used as an etching stop layer, and thus the depth of the groove can be actively controlled and adjusted according to the flow requirements of the packaging material.

In some embodiments, step (a11) includes:

As shown in FIG. 40, applying a seed layer 413 on the dielectric layer 412; wherein, the seed layer 413 may be made by a sputtering, chemical deposition process. Alternatively, the material of the seed layer 413 may be copper, copper+titanium. As shown in FIG. 4P, then, applying a fourth anti-plating film layer 414 on the seed layer 413, and forming a second wiring layer pattern 415 by exposure and development; finally, as shown in FIG. 4R, the second wiring layer 416 is formed by electroplating.

It will be understood by those skilled in the art that the process for forming the anti-plating film layer of each layer may be a conformable dry film or a coating, which is not limited in the disclosure. The material of each anti-plating film layer may be a photoresist material or other organic material, which is not limited herein.

Illustratively, the material of the first wiring layer, the second wiring layer, and the metal post in embodiments of the disclosure may be copper.

Finally, the carrier plate is removed—step (a12), as shown in FIGS. 4S-4U. Here, referring to FIG. 4S, the first metal layer 40 and the second metal layer 403 are separated, and the second metal layer 403 in contact with the dielectric layer 412 is etched, as shown in FIG. 4U.

Optionally, prior to etching the second metal layer 403 in contact with the dielectric layer 412, a step of removing the fourth anti-plating film layer 414 is also included (as shown in FIG. 4T). It will be understood by those skilled in the art that this step may also be performed before or after the separation of the first metal layer 40 and the second metal layer 403, which is not limited in the disclosure.

Note that the seed layer 413 is etched at the same time as the second metal layer 403 is etched. Note that the second metal layer 403 also serves as a seed layer for forming the first wiring layer.

Thus, after removing the carrier plate, the substrate 400 is obtained, and the substrate can be used for manufacturing an embedded trace substrate with sides exposed.

Next, with reference to the aforementioned steps (b) to (d), an embedded trace substrate with sides exposed is manufactured.

First, first resist layer 417, 418 are applied on the substrate 400, and a first opening 419 is formed by exposure and development, as shown in FIGS. 4V-4W. Here, the first resist layer 418 serves to protect the second wiring layer. Here, the projections of the first opening and the third opening on the substrate do not overlap. With such an arrangement, the dielectric layer in place of the second anti-plating film layer can act as an etch stop layer to control the etch depth of the first opening, thereby achieving effective control of the groove depth.

Next, the first wiring layer of the first opening is etched to form a groove 420, as shown in FIG. 4X.

Finally, the first resist layer 417, 418 are removed, i.e. to obtain a side-exposed embedded trace substrate, as shown in FIG. 4Y.

Here, the depth of the groove is less than the thickness of the first wiring layer, and the pad can be used for mounting the device 421; as shown in FIG. 4Z, a “gap” can be formed at the bottom of the device to facilitate the flow filling of the packaging resin material during the subsequent packaging process of the substrate, so as to avoid the technical problem of poor glue flow at the bottom of the device due to the excessively small “gap”.

Those of ordinary skill in the art will appreciate that the discussion of any embodiment above is merely exemplary and is not intended to imply that the scope of the disclosure, including the claims, is limited to these examples; combinations of features in the above embodiments, or between different embodiments, may also be made within the spirit of the disclosure, the steps may be implemented in any order, and there may be many other variations of the different aspects of the embodiments of the disclosure as described above, which are not provided in detail for clarity.

The disclosed embodiments are intended to embrace all such alternatives, modifications and variances which fall within the broad scope of the appended claims. Therefore, any omissions, modifications, equivalents, improvements, and the like that may be made without departing from the spirit or scope of the embodiments of the disclosure are intended to be included within the scope of the disclosure.

What is claimed is:

1. A side-exposed embedded trace substrate comprising:
a dielectric layer and a first wiring layer embedded in the dielectric layer;
wherein an outer surface of the first wiring layer is not higher than a surface of the dielectric layer, and the first wiring layer comprises a pad having a groove to increase a side-exposed area of the pad.

2. The embedded trace substrate of claim 1, wherein the groove is located at an edge or a middle of the pad.

3. The embedded trace substrate of claim 1, wherein a depth of the groove is less than a thickness of the first wiring layer, and the pad is configured to be used to mount a device.

4. The embedded trace substrate of claim 1, wherein a depth of the groove is equal to a thickness of the first wiring layer and the pad is configured to be used to weld a device.

5. The embedded trace substrate of claim 1, wherein the first wiring layer comprises a first sub-layer and a second sub-layer below the first sub-layer, an upper surface of the first sub-layer being flush with a surface of the dielectric layer; the groove is surrounded by the first sub-layer and exposes a dielectric layer surrounded by the second sub-layer.

6. A method for manufacturing a side-exposed embedded trace substrate, the method comprising:
(a) providing a substrate comprising a dielectric layer and a first wiring layer embedded in the dielectric layer;
(b) applying a first resist layer on the substrate and forming a first opening by exposure and development, wherein the first opening exposes at least a partial region of a pad of the first wiring layer;
(c) etching the first wiring layer exposed by the first opening to form a groove in a partial region of the pad; and
(d) removing the first resist layer to obtain the side-exposed embedded trace substrate.

7. The method of claim 6, wherein the etching process is acid etching or alkaline etching.

8. The method of claim 6, wherein the first opening is located at an edge of the pad or a middle of the pad.

9. The method of claim 6, wherein a depth of the groove is less than a thickness of the first wiring layer; or
the depth of the groove is equal to the thickness of the first wiring layer.

10. The method of claim 6, wherein the step (a) comprises:
(a1) providing a carrier plate;
(a2) applying a first anti-plating film layer on the carrier plate, and forming a second opening by exposure and development;
(a3) forming a first sub-layer of the first wiring layer in the second opening by electroplating;
(a4) applying a second anti-plating film layer on the first anti-plating film layer and the first sub-layer, and forming a third opening by exposure and development; wherein the second anti-plating film layer corresponding to the side-exposed region of the pad is retained;
(a5) forming a second sub-layer of the first wiring layer in the third opening by electroplating;
(a6) removing the first anti-plating film layer and the second anti-plating film layer;
(a7) forming a third anti-plating film layer on the carrier plate and the first wiring layer, and forming a fourth opening by exposure and development;
(a8) forming a metal post in the fourth opening by electroplating;
(a9) removing the third anti-plating film layer;
(a10) laminating a dielectric layer, thinning the dielectric layer until the metal post is exposed;
(a11) forming a second wiring layer on the dielectric layer; and
(a12) removing the carrier plate.

11. The method of claim 10, wherein the projections of the first opening and the third opening on the substrate do not overlap.

12. The method of claim 10, wherein the step (a11) comprises:
applying a seed layer on the dielectric layer;
applying a fourth anti-plating film layer on the seed layer, and forming a second wiring layer pattern by exposure and development; and
forming the second wiring layer by electroplating.

13. The method of claim 10, wherein the carrier plate comprises a first metal layer and a second metal layer; and
the step (a12) comprises separating the first metal layer and the second metal layer and etching the second metal layer in contact with the dielectric layer.
